(19) United States
(12) Patent Application Publication
(10) Pub. No.: US 2026/0096491 A1
(43) Pub. Date: Apr. 2, 2026

(54) SEMICONDUCTOR DEVICE AND VEHICLE

(71) Applicant: Rohm Co., Ltd., Kyoto-shi (JP)

(72) Inventors: Tomoki FUJIMURA, Kyoto-shi (JP); Daiki IKEDA, Kyoto-shi (JP)

(21) Appl. No.: 19/411,915

(22) Filed: Dec. 8, 2025

Related U.S. Application Data
(63) Continuation of application No. PCT/JP2024/018300, filed on May 17, 2024.

(30) Foreign Application Priority Data
Jun. 15, 2023 (JP) 2023-098411

(51) Int. Cl. H10W 90/10; H10D 80/20; H10W 70/60; H10W 70/652; H10W 70/654; H10W 72/60; H10W 90/00

(52) U.S. Cl. CPC H10W 90/10; H10D 80/251; H10W 70/611; H10W 70/6528; H10W 70/654; H10W 72/634; H10W 72/637; H10W 90/763; H10W 90/764; H10W 90/794

(57) ABSTRACT

A semiconductor device includes a first conductive portion, a second conductive portion, a first semiconductor element, a second semiconductor element, two first terminals, a second terminal, a third terminal, a first conductive member, a second conductive member, a plurality of first control terminals, a plurality of second control terminals, and a sealing resin. In a first direction orthogonal to the thickness direction, the first conductive portion and the second conductive portion are spaced apart from each other. The second terminal and the second conductive member form a conduction path located outside the plurality of first control terminals in a second direction orthogonal to the thickness direction and the first direction.

### TECHNICAL FIELD

The present disclosure relates to a semiconductor device and a vehicle.

### BACKGROUND ART

Conventionally, semiconductor devices including power switching elements such as MOSFETs (Metal Oxide Semiconductor Field Effect Transistors) or IGBTs (Insulated Gate Bipolar Transistors) are known. JP-A-2021-190505 discloses a conventional semiconductor device (power module). The semiconductor device disclosed in JP-A-2021-190505 includes an input terminal and an output terminal through which the main current, which is to be switched, flows, and a plurality of control terminals.

### BRIEF DESCRIPTION OF THE DRAWINGS

FIG. 1 is a perspective view of a main part of a semiconductor device according to a first embodiment of the present disclosure.

FIG. 2 is a perspective view of the main part of the semiconductor device according to the first embodiment of the present disclosure.

FIG. 3 is a plan view of the semiconductor device according to the first embodiment of the present disclosure.

FIG. 4 is a plan view of the main part of the semiconductor device according to the first embodiment of the present disclosure.

FIG. 5 is a side view of the main part of the semiconductor device according to the first embodiment of the present disclosure.

FIG. 6 is a plan view of the main part of the semiconductor device according to the first embodiment of the present disclosure.

FIG. 7 is a plan view of the main part of the semiconductor device according to the first embodiment of the present disclosure.

FIG. 8 is a side view of the semiconductor device according to the first embodiment of the present disclosure.

FIG. 9 is a bottom view of the semiconductor device according to the first embodiment of the present disclosure.

FIG. 10 is a sectional view taken along line X-X in FIG. 4.

FIG. 11 is a sectional view taken along line XI-XI in FIG. 4.

FIG. 12 is an enlarged sectional view of the main part of the semiconductor device according to the first embodiment of the present disclosure.

FIG. 13 is an enlarged sectional view of the main part of the semiconductor device according to the first embodiment of the present disclosure.

FIG. 14 is a sectional view taken along line XIV-XIV in FIG. 4.

FIG. 15 is a sectional view taken along line XV-XV in FIG. 4.

FIG. 16 is a sectional view taken along line XVI-XVI in FIG. 4.

FIG. 17 is a sectional view taken along line XVII-XVII in FIG. 4.

FIG. 18 is a sectional view taken along line XVIII-XVIII in FIG. 4.

FIG. 19 is a circuit diagram of the semiconductor device according to the first embodiment of the present disclosure.

FIG. 20 is a system configuration diagram of a vehicle in which the semiconductor device according to the first embodiment of the present disclosure is mounted.

FIG. 21 is a sectional view of a semiconductor device according to a second embodiment of the present disclosure.

FIG. 22 is a plan view of a part of a semiconductor device according to a third embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

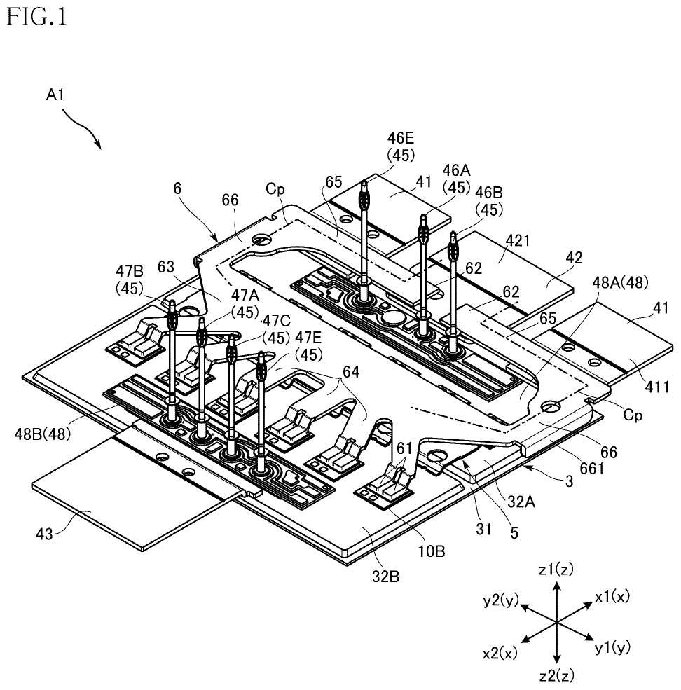

FIGS. 1 to 19 show a semiconductor device according to a first embodiment of the present disclosure. The semiconductor device A1 of the present embodiment includes a plurality of first semiconductor elements 10A, a plurality of second semiconductor elements 10B, a support substrate 3, a second terminal 42, a third terminal 43, two first terminals 41, a plurality of control terminals 45, a control terminal support 48, a first conductive member 5, a second conductive member 6, and a sealing resin 8.

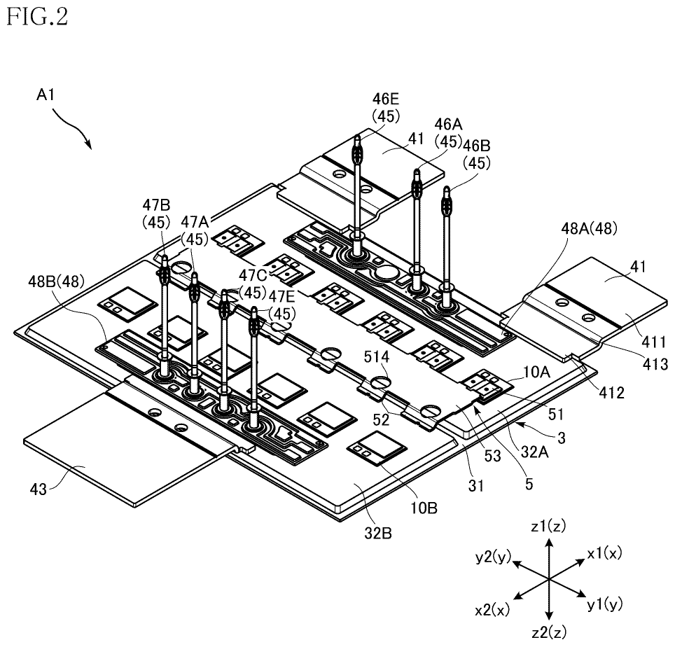

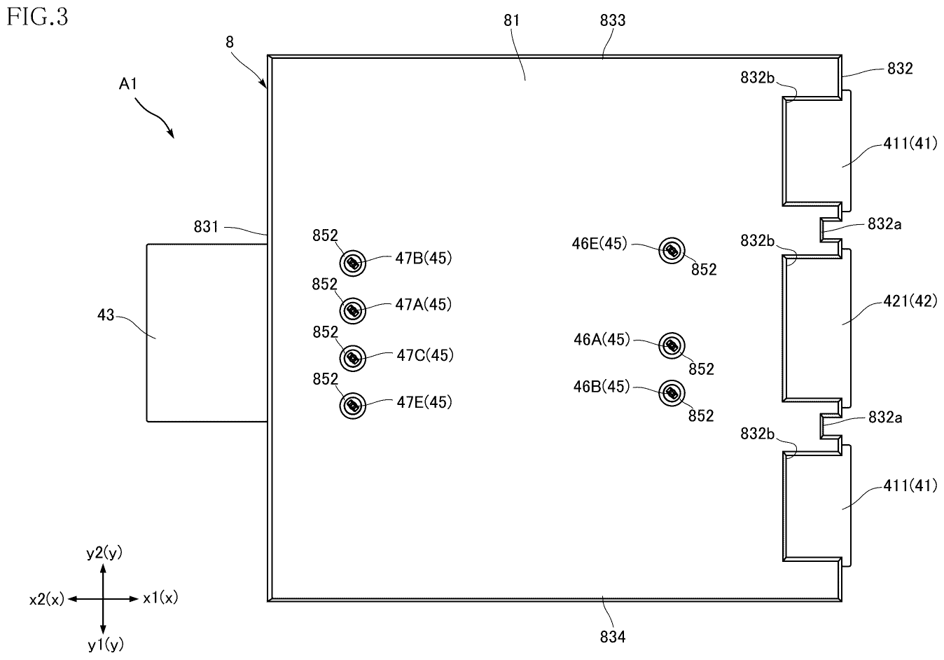

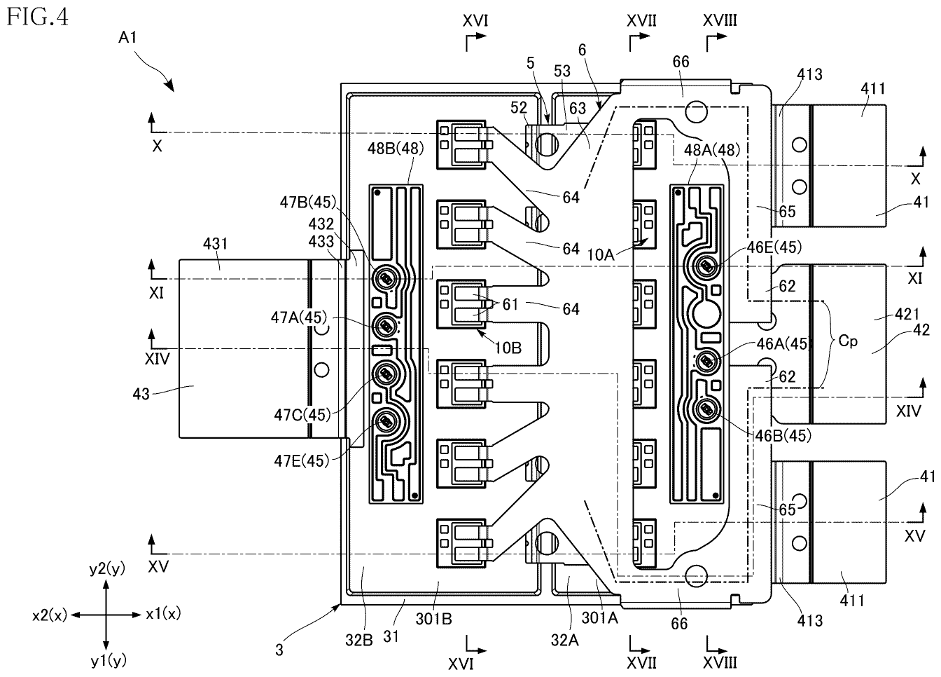

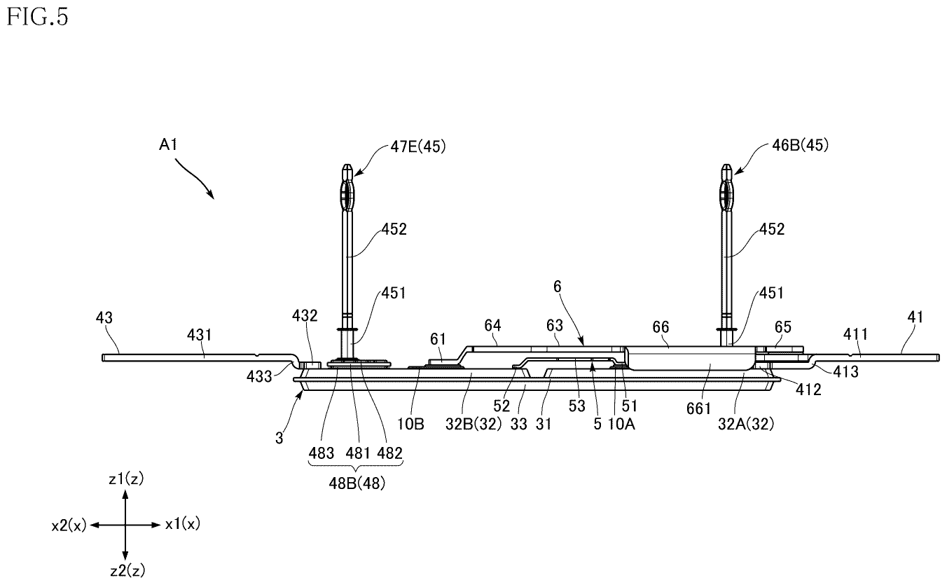

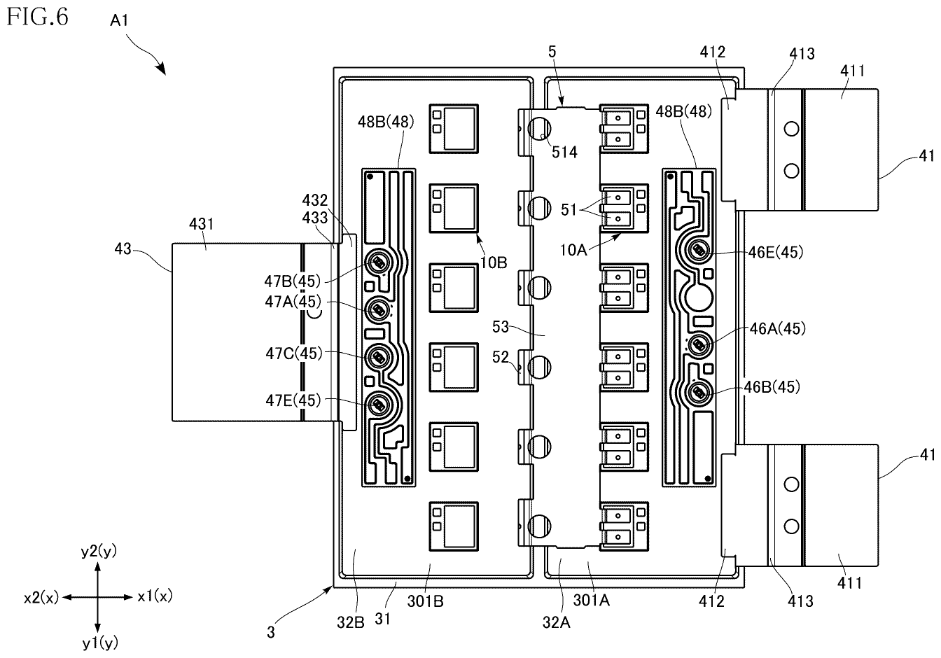

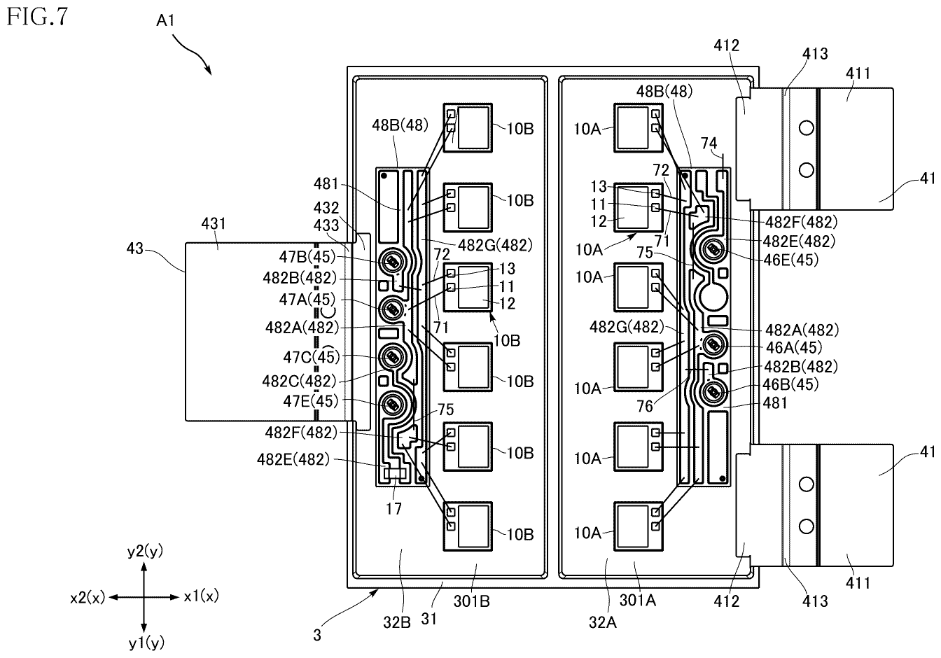

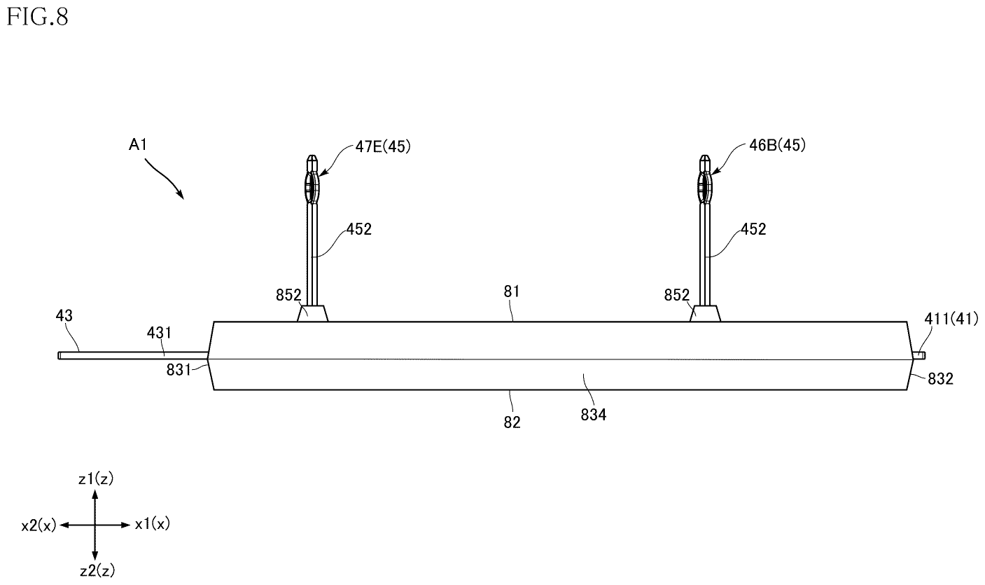

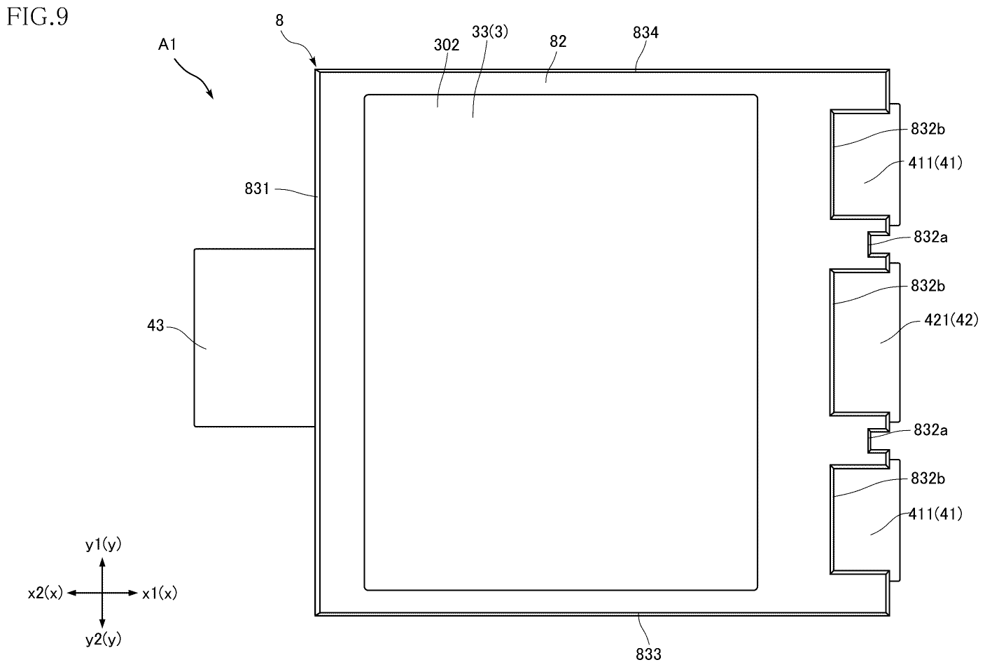

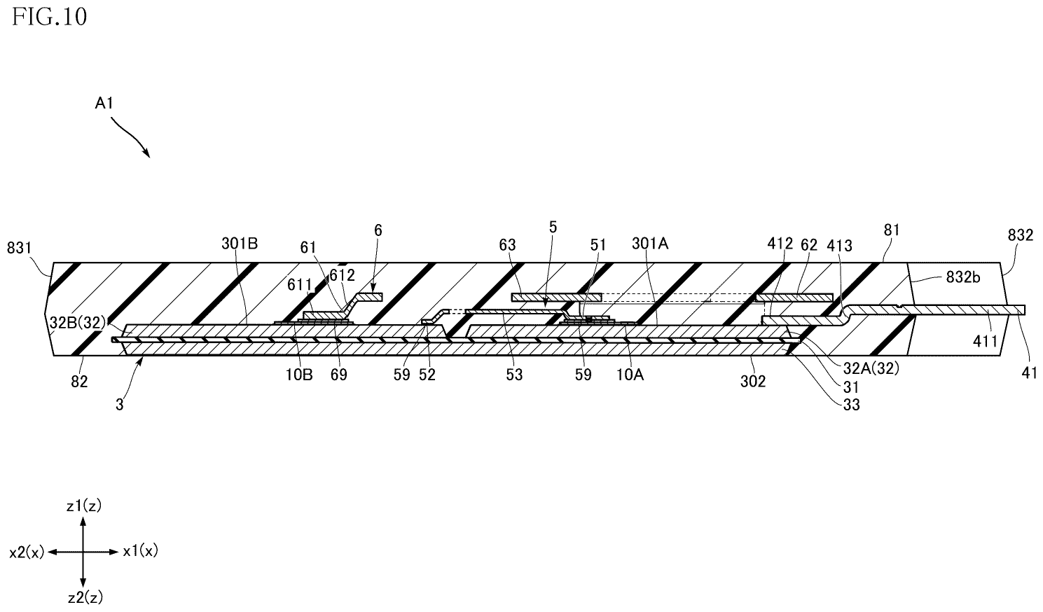

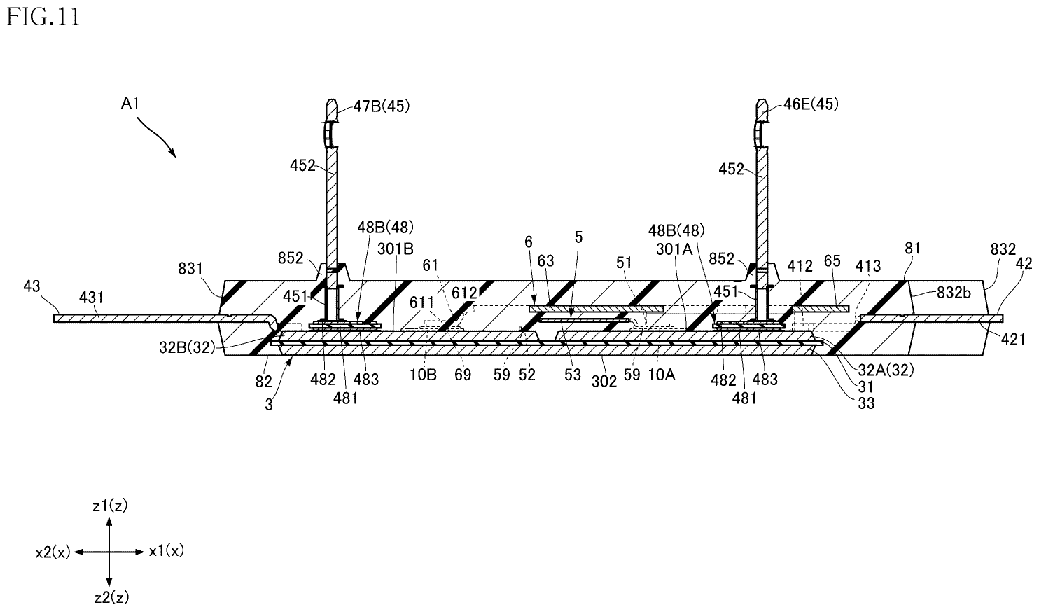

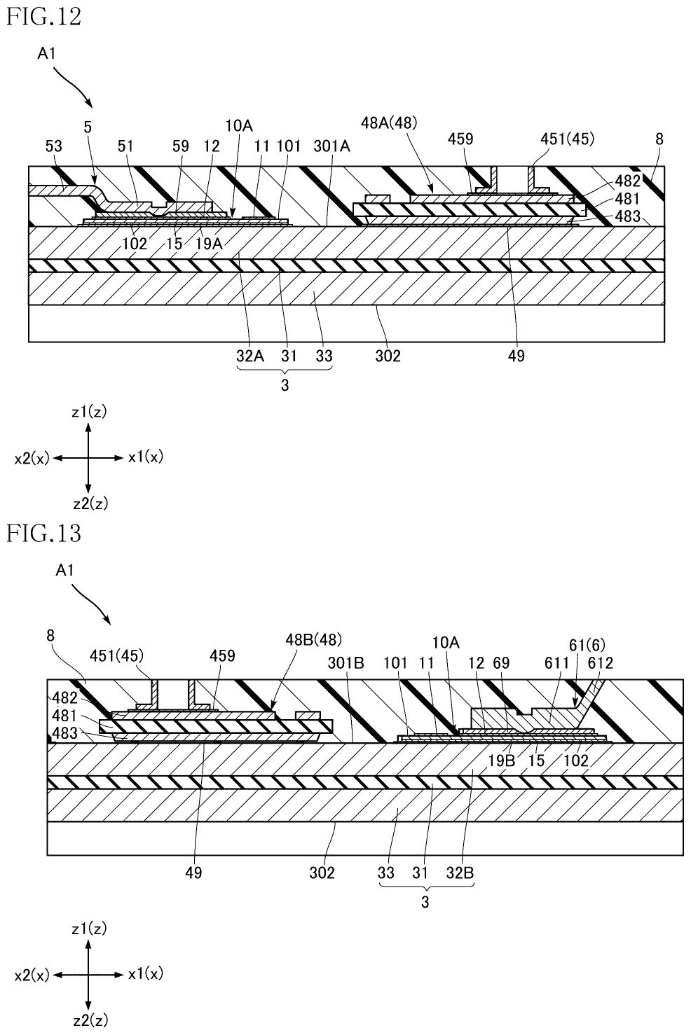

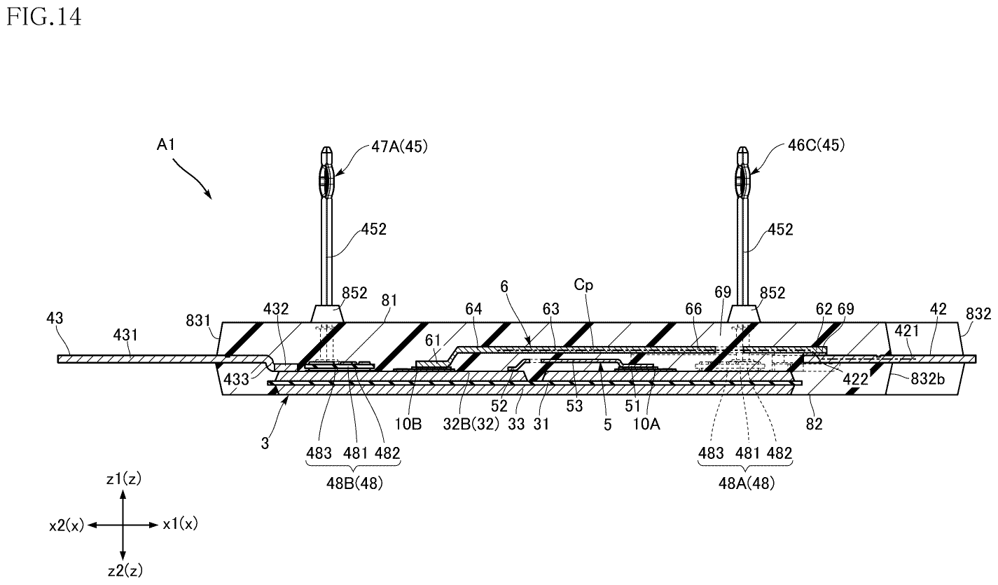

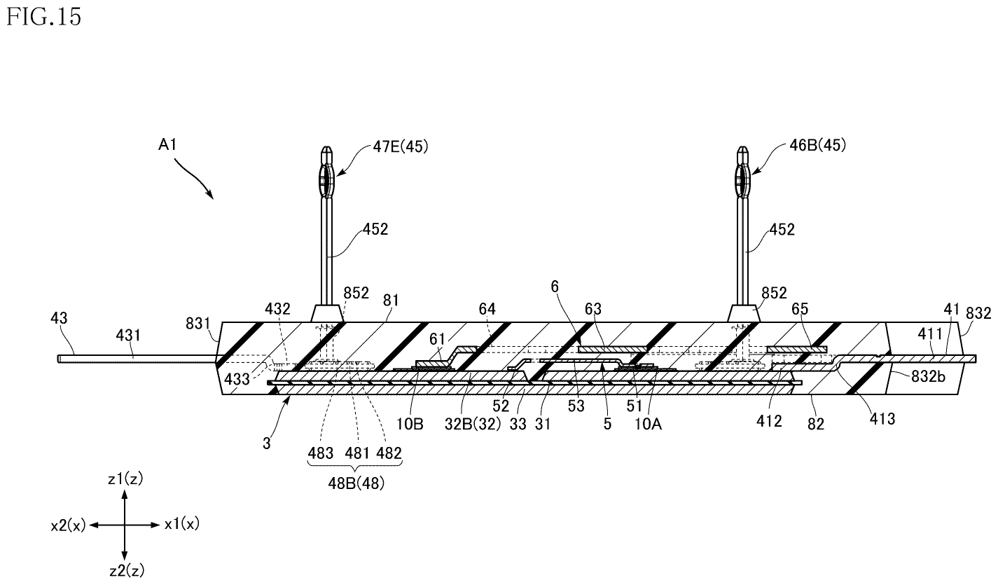

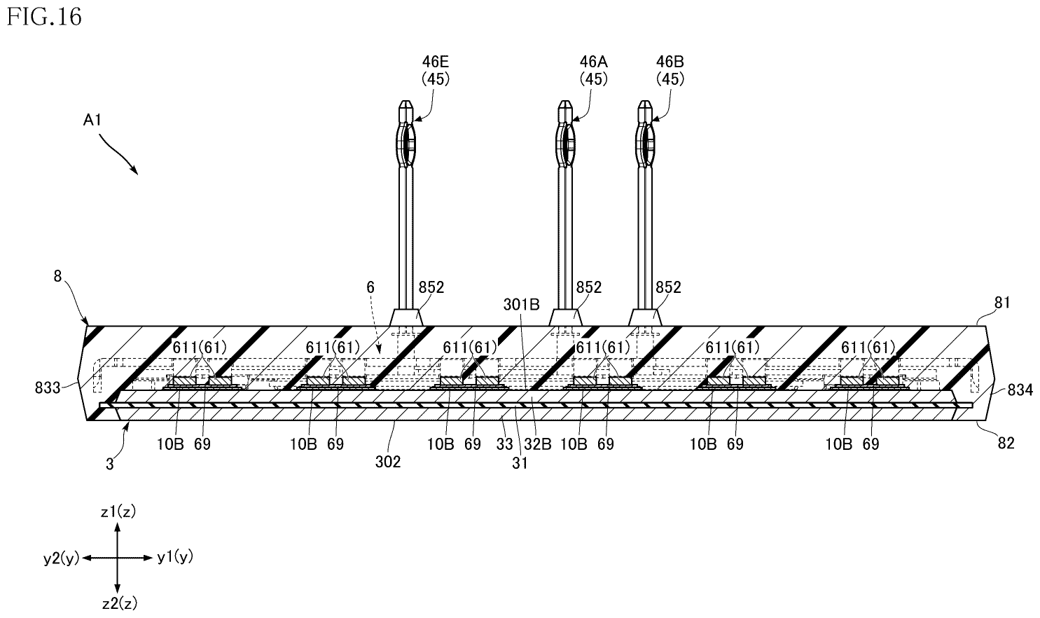

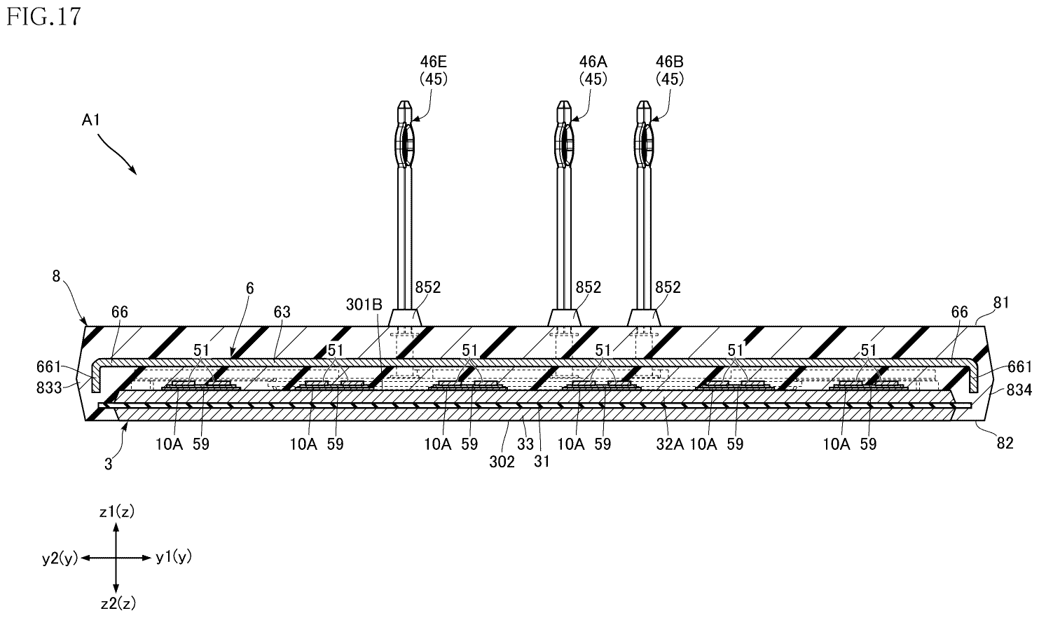

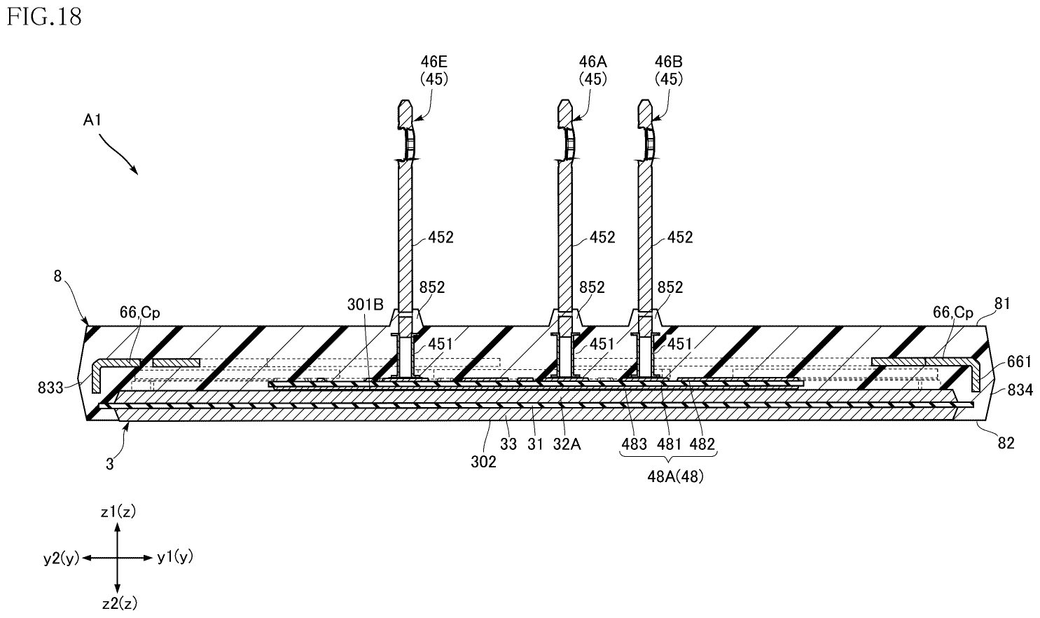

FIG. 1 is a perspective view of a main part of the semiconductor device A1. FIG. 2 is a perspective view of the main part of the semiconductor device A1. FIG. 3 is a plan view of the semiconductor device A1. FIG. 4 is a plan view of the main part of the semiconductor device A1. FIG. 5 is a side view of the main part of the semiconductor device A1. FIG. 6 is a plan view of the main part of the semiconductor device A1. FIG. 7 is a plan view of the main part of the semiconductor device A1. FIG. 8 is a side view of the semiconductor device A1. FIG. 9 is a bottom view of the semiconductor device A1. FIG. 10 is a sectional view taken along line X-X in FIG. 4. FIG. 11 is a sectional view taken along line XI-XI in FIG. 4. FIG. 12 is an enlarged sectional view of the main part of the semiconductor device A1. FIG. 13 is an enlarged sectional view of the main part of the semiconductor device A1. FIG. 14 is a sectional view taken along line XIV-XIV in FIG. 4. FIG. 15 is a sectional view taken along line XV-XV in FIG. 4. FIG. 16 is a sectional view taken along line XVI-XVI in FIG. 4. FIG. 17 is a sectional view taken along line XVII-XVII in FIG. 4. FIG. 18 is a sectional view taken along line XVIII-XVIII in FIG. 4. FIG. 19 is a circuit diagram of the semiconductor device A1.

In these figures, for example, the thickness direction z is the “thickness direction” of the present disclosure, the first direction x is the “first direction” of the present disclosure, and the second direction y is the “second direction” of the present disclosure.

The first semiconductor elements 10A and the second semiconductor elements 10B are electronic components that form the functional core of the semiconductor device A1. The constituent material of the first semiconductor elements 10A and the second semiconductor elements 10B is a semiconductor material mainly composed of, for example, SiC (silicon carbide). The semiconductor material is not limited to SiC, but may be Si (silicon), GaN (gallium nitride), or C (diamond), for example. The first semiconductor elements 10A and the second semiconductor elements 10B may be power semiconductor chips having a switching function, such as MOSFETs (Metal Oxide Semiconductor Field Effect Transistors). The first semiconductor elements 10A and the second semiconductor elements 10B are MOSFETs in the present embodiment, but are not limited to this, and may be other transistors, such as IGBTs (Insulated Gate Bipolar Transistors). The first semiconductor elements 10A and the second semiconductor elements 10B are all of the same type. The first semiconductor elements 10A and the second semiconductor elements 10B are, for example, n-channel MOSFETs, but may be p-channel MOSFETs.

As shown in FIGS. 7, 12, and 13, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

In the present embodiment, the semiconductor device A1 includes four first semiconductor elements 10A and four second semiconductor elements 10B. However, the number of first semiconductor elements 10A and the number of second semiconductor elements 10B are not limited to this, and may be changed as appropriate in accordance with the performance required of the semiconductor device A1. In the example of FIGS. 6 and 7, four each of the first semiconductor elements 10A and the second semiconductor elements 10B are provided. The number of first semiconductor elements 10A and the number of second semiconductor elements 10B may be two, three, or five or greater. The number of first semiconductor elements 10A and the number of second semiconductor elements 10B may be the same or may be different. The number of first semiconductor elements 10A and the number of second semiconductor elements 10B are determined based on the current capacity of the semiconductor device A1.

As shown in FIG. 19, the semiconductor device A1 may be configured as a half-bridge type switching circuit. In such a case, in the semiconductor device A1, the first semiconductor elements 10A form the upper arm circuit, and the second semiconductor elements 10B form the lower arm circuit. In the upper arm circuit, the first semiconductor elements 10A are connected in parallel with each other. In the lower arm circuit, the second semiconductor elements 10B are connected in parallel with each other. The first semiconductor elements 10A and the second semiconductor element 10B are connected in series to form bridge layers.

As shown in FIGS. 6, 7, and 17, each of the first semiconductor elements 10A is mounted on the first conductive portion 32A of the support substrate 3, described later. In the example shown in FIGS. 6 and 7, the first semiconductor elements 10A are, for example, aligned in the second direction y and are spaced apart from each other. The first semiconductor elements 10A may be spaced apart from each other in the second direction y and disposed at positions different from each other in the first direction x. Each of the first semiconductor elements 10A is conductively bonded to the first conductive portion 32A via a first conductive bonding material 19A. When each first semiconductor element 10A is bonded to the first conductive portion 32A, the element reverse surface 102 faces the first conductive portion 32A. Unlike the present embodiment, the first semiconductor elements 10A may be mounted on a metal member different from a portion of the DBC substrate or the like. In such a case, the metal member corresponds to the first conductive portion of the present disclosure. The metal member may be supported on the first conductive portion 32A.

As shown in FIGS. 6, 7, and 16 in particular, each of the second semiconductor elements 10B is mounted on the second conductive portion 32B of the support substrate 3, described later. In the example shown in FIGS. 6 and 7, the second semiconductor elements 10B are, for example, aligned in the second direction y and are spaced apart from each other. The second semiconductor elements 10B may be spaced apart from each other in the second direction y and disposed at positions different from each other in the first direction x. Each of the second semiconductor elements 10B is conductively bonded to the second conductive portion 32B via a second conductive bonding material 19B. When each second semiconductor element 10B is bonded to the second conductive portion 32B, the element reverse surface 102 faces the second conductive portion 32B. The first semiconductor elements 10A and the second semiconductor elements 10B overlap with each other as viewed in the first direction x as understood from FIG. 7, but may not overlap with each other. Unlike the present embodiment, the second semiconductor elements 10B may be mounted on a metal member different from a portion of the DBC substrate or the like. In such a case, the metal member corresponds to the second conductive portion of the present disclosure. The metal member may be supported on the second conductive portion 32B.

The first semiconductor elements 10A and the second semiconductor elements 10B each have a gate electrode 11, a source electrode 12, a source sense electrode 13, and a drain electrode 15. The configuration of the gate electrode 11, the source electrode 12, the source sense electrode 13, and the drain electrode 15 described below is common to the first semiconductor elements 10A and the second semiconductor elements 10B. The gate electrode 11, the source electrode 12, and the source sense electrode 13 are provided on the element obverse surface 101. The gate electrode 11, the source electrode 12, and the source sense electrode 13 are insulated by an insulating film, not shown. The drain electrode 15 is provided on the element reverse surface 102.

The drain electrode 15 is an example of the first electrode of the present disclosure. The drain electrode 15 is the positive electrode of the current path to be switched in the semiconductor device A1. The drain electrode 15 covers the entire area (or almost entire area) of the element reverse surface 102. The drain electrode 15 is made of Ag (silver) plating, for example. The source electrode 12 is an example of the second electrode of the present disclosure. The source electrode 12 is the negative electrode of the current path to be switched in the semiconductor device A1. The gate electrode 11 is an example of the third electrode of the present disclosure. The gate electrode 11 is an electrode for switching the state of conduction between the drain electrode 15 and the source electrode 12, and a drive signal (e.g., gate voltage) for driving the first semiconductor element 10A (the second semiconductor element 10B) is inputted to the gate electrode. The source sense electrode 13 is an electrode with the same potential as the source electrode 12.

Each of the first semiconductor elements 10A (the second semiconductor elements 10B) switches between a conducting state and a non-conducting state in response to a drive signal (gate voltage) inputted to the gate electrode 11. In the conducting state, a current flows from the drain electrode 15 to the source electrode 12. In the non-conducting state, this current does not flow. That is, each first semiconductor element 10A (each second semiconductor element 10B) performs a switching operation. The semiconductor device A1 uses the switching function of the first semiconductor elements 10A and the second semiconductor elements 10B to convert the DC voltage inputted between the two first terminals 41 and the second terminal 42 into e.g. AC voltage and outputs the AC voltage from the third terminal 43.

The support substrate 3 supports the first semiconductor elements 10A and the second semiconductor elements 10B. The specific configuration of the support substrate 3 is not limited in any way and may be made of a DBC (Direct Bonded Copper) substrate or an AMB (Active Metal Brazing) substrate, for example. The support substrate 3 includes an insulating layer 31, a first metal layer 32, and a reverse-surface metal layer 33. The first metal layer 32 includes the first conductive portion 32A and the second conductive portion 32B. The dimension in the thickness direction z of the support substrate 3 is, for example, equal to greater than 0.4 mm and equal to or less than 3.0 mm.

The insulating layer 31 is made of, for example, a ceramic material with excellent thermal conductivity. Such a ceramic material includes SiN (silicon nitride), for example. The insulating layer 31 is not limited to a ceramic material and may be an insulating resin sheet or the like. The insulating layer 31 may be rectangular in plan view. The dimension in the thickness direction z of the insulating layer 31 is, for example, equal to greater than 0.05 mm and equal to or less than 1.0 mm.

The first conductive portion 32A supports the first semiconductor elements 10A, and the second conductive portion 32B supports the second semiconductor elements 10B. The first conductive portion 32A and the second conductive portion 32B are formed on the upper surface (the surface facing the z1 side in the thickness direction z) of the insulating layer 31. The constituent material of the first conductive portion 32A and the second conductive portion 32B includes Cu (copper), for example. The constituent material may include A1 (aluminum) rather than Cu. The first conductive portion 32A and the second conductive portion 32B are spaced apart from each other in the first direction x. The first conductive portion 32A is located on the x1 side in the first direction x of the second conductive portion 32B. Each of the first conductive portion 32A and the second conductive portion 32B may be rectangular in plan view. The first conductive portion 32A and the second conductive portion 32B, together with the first conductive member 5 and the second conductive member 6, form a path for the main circuit current switched by the first semiconductor elements 10A and the second semiconductor elements 10B.

The first conductive portion 32A has a first obverse surface 301A. The first obverse surface 301A is a flat surface facing the z1 side in the thickness direction z. The first semiconductor elements 10A are bonded to the first obverse surface 301A of the first conductive portion 32A via the first conductive bonding materials 19A. The second conductive portion 32B has a second obverse surface 301B. The second obverse surface 301B is a flat surface facing the z1 side in the thickness direction z. The second semiconductor elements 10B are bonded to the second obverse surface 301B of the second conductive portion 32B via the second conductive bonding materials 19B. The constituent material of the first conductive bonding materials 19A and the second conductive bonding materials 19B is not particularly limited, and may be solder, metal paste containing a metal such as Ag (silver), or sintered metal containing a metal such as Ag (silver), for example. The dimension in the thickness direction z of the first conductive portion 32A and the second conductive portion 32B is, for example, equal to greater than 0.1 mm and equal to or less than 1.5 mm.

The reverse-surface metal layer 33 is formed on the lower surface (the surface facing the z2 side in the z direction) of the insulating layer 31. The constituent material of the reverse-surface metal layer 33 is the same as that of the first metal layer 32. The reverse-surface metal layer 33 has a reverse surface 302. The reverse surface 302 is a flat surface facing the z2 side in the thickness direction z. In the example shown in FIG. 9, the reverse surface 302 may be exposed from the sealing resin 8. A heat dissipating member (e.g., a heat sink), not shown, can be attached to the reverse surface 302. The reverse surface 302 may not be exposed from the sealing resin 8 and may be covered with the sealing resin 8. The reverse-surface metal layer 33 overlaps with both of the first conductive portion 32A and the second conductive portion 32B in plan view.

Each of the second terminal 42, the third terminal 43, and the two first terminals 41 is made of a metal plate. The metal plate contains, for example, Cu (copper) or a Cu (copper) alloy.

As shown in FIG. 19, the DC voltage to be converted is inputted to the second terminal 42 and the first terminals 41. The first terminals 41 are positive electrodes (P terminal), and the second terminal 42 is a negative electrode (N terminal). The AC voltage converted by the first semiconductor elements 10A and the second semiconductor elements 10B is outputted from the third terminal 43. Each of the second terminal 42, the third terminal 43, and the two first terminals 41 includes a portion covered with the sealing resin 8 and a portion exposed from the sealing resin 8.

The two first terminals 41 are spaced apart from each other in the second direction y, as shown in FIGS. 1 to 7. Each of the two first terminals 41 is connected to the first obverse surface 301A of the first conductive portion 32A. The two first terminals 41 are located on the x1 side in the first direction x with respect to the first semiconductor elements 10A, as shown in FIGS. 6 and 7 in particular. The two first terminals 41 electrically conduct to the first conductive portion 32A and also electrically conduct to the drain electrode 15 of each of the first semiconductor elements 10A via the first conductive portion 32A. In the present embodiment, the first terminal 41 has a first terminal portion 411, a first connection portion 412, and a first step portion 413.

The first terminal portion 411 is exposed from the sealing resin 8 and used to electrically connect the semiconductor device A1 to an external device. The first connection portion 412 is conductively bonded to the first obverse surface 301A of the first conductive portion 32A, as shown in FIGS. 10 and 15. The methods of conductive bonding are not limited, and methods such as ultrasonic bonding, laser bonding, welding, or other methods using solder, metal paste, sintered silver or the like are used as appropriate. The first step portion 413 is interposed between the first terminal portion 411 and the first connection portion 412, causing a difference in position in the thickness direction z between the first terminal portion 411 and the first connection portion 412.

The second terminal 42 electrically conducts to the source electrodes 12 of the second semiconductor elements 10B via the second conductive member 6. In the present embodiment, the second terminal 42 and the second conductive member 6 are formed separately from each other and conductively bonded to each other. The second terminal 42 and the second conductive member 6 may be an integral unit. The integral unit refers to a configuration that is formed by cutting and bending a single metal plate, for example, and that does not include a bonding material or the like for bonding them together. As shown in FIGS. 1 and 4, the second terminal 42 is located between the two first terminals 41 in the second direction y. The second terminal 42 is located on the x1 side in the first direction x with respect to the first semiconductor elements 10A. In the present embodiment, the second terminal 42 has a second terminal portion 421 and a second connection portion 422, as shown in FIG. 14.

The second terminal portion 421 is exposed from the sealing resin 8 and used to electrically connect the semiconductor device A1 to an external device. The second terminal portion 421 is located between two first terminal portions 411 in the second direction y. The second terminal portion 421 is exposed from the sealing resin 8. The second connection portion 422 extends from the second terminal portion 421 to the x2 side in the first direction x.

As understood from FIGS. 6, 7, and 14, the third terminal 43 is conductively bonded to the second conductive portion 32B. The methods of conductive bonding are not limited, and methods such as ultrasonic bonding, laser bonding, welding, or other methods using solder, metal paste, sintered silver or the like are used as appropriate. As shown in FIG. 6 in particular, the third terminal 43 is located on the x2 side in the first direction x with respect to the second semiconductor elements 10B. The third terminal 43 electrically conducts to the second conductive portion 32B and also electrically conducts to the drain electrode 15 of each of the second semiconductor elements 10B via the second conductive portion 32B. The number of third terminal 43 is not limited to one, but may be two or greater, for example.

In the present embodiment, the third terminal 43 has a third terminal portion 431 and a third connection portion 432. The third terminal portion 431 is exposed from the sealing resin 8 and used to electrically connect the semiconductor device A1 to an external device. The third connection portion 432 extends from the third terminal portion 431 to the x1 side in the first direction x. The third connection portion 432 is conductively bonded to the second obverse surface 301B of the second conductive portion 32B.

The control terminals 45 are pin-shaped terminals for controlling the first semiconductor elements 10A and the second semiconductor elements 10B. The control terminals 45 include a plurality of first control terminals 46A, 46B, and 46E and a plurality of second control terminals 47A, 47B, 47C, and 47E. The first control terminals 46A, 46B, and 46E are used to control the first semiconductor elements 10A, for example. The second control terminals 47A, 47B, 47C, and 47E are used to control the second semiconductor elements 10B, for example.

The first control terminals 46A, 46B and 46E are spaced apart from each other in the second direction y. In the illustrated example, the first control terminals 46A, 46B, and 46E are arranged approximately in a straight line along the second direction y. However, the present disclosure is not limited to such an arrangement. For example, the positions of the first control terminals in the first direction may be different from each other. The first control terminals 46A, 46B, and 46E protrude from the sealing resin 8 to the z1 side in the thickness direction z, as shown in FIGS. 6, 11, and 18 in particular. The first control terminals 46A, 46B, and 46E are supported on the first conductive portion 32A via the control terminal support 48 (the first support portion 48A described later). As shown in FIGS. 4 and 6, the first control terminals 46A, 46B, and 46E are located between the first semiconductor elements 10A and the second and the first terminals 42 and 41 in the first direction x.

The first control terminal 46A is a terminal (a gate terminal) for inputting a drive signal for the first semiconductor elements 10A. A drive signal for driving the first semiconductor elements 10A is inputted (e.g., a gate voltage is applied) to the first control terminal 46A.

The first control terminal 46B is a terminal (a source sense terminal) for detecting a source signal of the first semiconductor elements 10A. The voltage applied to the source electrode 12 of each first semiconductor element 10A (the voltage corresponding to the source current) is detected from the first control terminal 46B.

The first control terminal 46E is a terminal (a drain sense terminal) for detecting a drain signal of the first semiconductor elements 10A. The voltage applied to the drain electrode 15 of each first semiconductor element 10A (the voltage corresponding to the drain current) is detected from the first control terminal 46E.

The second control terminals 47A, 47B, 47C, and 47E are spaced apart from each other in the second direction y. In the illustrated example, the second control terminals 47A, 47B, 47C, and 47E are arranged approximately in a straight line along the second direction y. However, the present disclosure is not limited to such an arrangement. For example, the positions of the second control terminals in the first direction may be different from each other. As shown in FIGS. 6 and 11, in particular, the second control terminals 47A, 47B, 47C, and 47E are supported on the second conductive portion 32B via the control terminal support 48 (the second support portion 48B described later). As shown in FIGS. 4 and 6, the second control terminals 47A, 47B, 47C, and 47E are located between the second semiconductor elements 10B and the third terminal 43 in the first direction x.

The second control terminal 47A is a terminal (a gate terminal) for inputting a drive signal for the second semiconductor elements 10B. A drive signal for driving the second semiconductor elements 10B is inputted (e.g., a gate voltage is applied) to the second control terminal 47A.

The second control terminal 47B is a terminal (a source sense terminal) for detecting a source signal of the second semiconductor elements 10B. The voltage applied to the source electrode 12 of each second semiconductor element 10B (the voltage corresponding to the source current) is detected from the second control terminal 47B.

The second control terminals 47C and 47E are used for temperature detection using a thermistor 17.

Each of the control terminals 45 (the first control terminals 46A to 46E and the second control terminals 47A to 47D) includes a holder 451 and a metal pin 452.

The holder 451 is made of an electrically conductive material. As shown in FIGS. 12 and 13, the holder 451 is bonded to the control terminal support 48 (the first metal layer 482, described later) via a conductive bonding material 459. The holder 451 includes a tubular portion, an upper-end flange portion, and a lower-end flange portion. The upper-end flange portion is connected to the upper part of the tubular portion, and the lower-end flange portion is connected to the lower part of the tubular portion. The metal pin 452 is inserted in at least the upper-end flange portion and the tubular portion of the holder 451. The holder 451 is covered with the sealing resin 8 (the second protrusion 852 described later).

The metal pin 452 is a bar-shaped member extending in the thickness direction z. The metal pin 452 is supported by being press-fitted into the holder 451. The metal pin 452 electrically conducts to the control terminal support 48 (the first metal layer 482, described below) at least via the holder 451.

The control terminal support 48 supports the control terminals 45. The control terminal support 48 is interposed between the first and the second obverse surfaces 301A and 301B and the control terminals 45 in the thickness direction z.

The control terminal support 48 includes a first support portion 48A and a second support portion 48B. The first support portion 48A is disposed on the first conductive portion 32A and supports the first control terminals 46A to 46E of the control terminals 45. As shown in FIG. 12, the first support portion 48A is bonded to the first conductive portion 32A via a bonding material 49. The bonding material 49 may be electrically conductive or insulating, and may be solder, for example. The second support portion 48B is disposed on the second conductive portion 32B and supports the second control terminals 47A to 47D of the control terminals 45. As shown in FIG. 13, the second support portion 48B is bonded to the second conductive portion 32B via a bonding material 49.

The control terminal support 48 (each of the first support portion 48A and the second support portion 48B) is made of a DBC (Direct Bonded Copper) substrate, for example. The control terminal support 48 includes an insulating layer 481, a first metal layer 482, and a second metal layer 483 laminated on top of each other.

The insulating layer 481 is made of, for example, a ceramic material. The insulating layer 481 may be rectangular in plan view.

As shown in FIGS. 12 and 13 in particular, the first metal layer 482 is formed on the upper surface of the insulating layer 481. The control terminals 45 are disposed on the first metal layer 482. The first metal layer 482 contains, for example, Cu (copper) or a Cu (copper) alloy. As shown in FIGS. 6 and 7, in particular, the first metal layer 482 includes a first portion 482A, a second portion 482B, a fifth portion 482E, a sixth portion 482F, and a seventh portion 482G. The first portion 482A, the second portion 482B, the fifth portion 482E, the sixth portion 482F, and the seventh portion 482G are spaced apart and insulated from each other.

The first portion 482A, to which a plurality of wires 71 are bonded, electrically conducts to the gate electrodes of the first semiconductor elements 10A (the second semiconductor elements 10B) via the wires 71. In the figures other than FIG. 7, the wires 71, 72, 74, 75, and 76 are omitted. The first control terminal 46A is bonded to the first portion 482A of the first support portion 48A, and the second control terminal 47A is bonded to the second portion 482B of the second support portion 48B.

The sixth portion 482F electrically conducts to the gate electrode 11 of one the first semiconductor element 10A via a wire 71. The sixth portion 482F electrically conducts to the first portion 482A via a wire 75.

The seventh portion 482G, to which a plurality of wires 72 are bonded, electrically conducts to the source sense electrodes 13 of the first semiconductor elements 10A (the second semiconductor elements 10B) via the wires 72. The seventh portion 482G electrically conducts to the second portion 482B via a wire 76. The first control terminal 46B is bonded to the second portion 482B of the first support portion 48A, and the second control terminal 47B is bonded to the second portion 482B of the second support portion 48B.

As shown in FIG. 6, the fifth portion 482E of the first support portion 48A, to which a wire 74 is bonded, electrically conducts to the first conductive portion 32A via the wire 74. The first control terminal 46E is bonded to the fifth portion 482E of the first support portion 48A.

A thermistor 17 is conductively bonded to the fifth portion 482E and the third portion 482C of the second support portion 48B. The second control terminal 47E is bonded to the fifth portion 482E of the second support portion 48B, and the second control terminal 47C is bonded to the third portion 482C of the second support portion 48B.

The wires 71, 72, 74, 75, and 76 may be bonding wires. The constituent material of the wires 71, 72 and 74 includes, for example, one of Au (gold), A1 (aluminum) or Cu (copper).

As shown in FIGS. 12 and 13 in particular, the second metal layer 483 is formed on the lower surface of the insulating layer 481. As shown in FIG. 12, the second metal layer 483 of the first support portion 48A is bonded to the first conductive portion 32A via a bonding material 49. As shown in FIG. 13, the second metal layer 483 of the second support portion 48B is bonded to the second conductive portion 32B via a bonding material 49.

The first conductive member 5 and the second conductive member 6, together with the first conductive portion 32A and the second conductive portion 32B, form a path for the main circuit current switched by the first semiconductor elements 10A and the second semiconductor elements 10B. The first conductive member 5 and the second conductive member 6 are located on the z1 side in the thickness direction z relative to the first obverse surface 301A and the second obverse surface 301B and overlap with the first obverse surface 301A and the second obverse surface 301B in plan view. In the present embodiment, the first conductive member 5 and the second conductive member 6 are made of metal plates. The metal includes, for example, Cu (copper) or a Cu (copper) alloy. Specifically, the first conductive member 5 and the second conductive member 6 are metal plates that are bent as appropriate.

As shown in FIGS. 2 and 6, the first conductive member 5 is connected to the source electrode 12 of each first semiconductor element 10A and the second conductive portion 32B to electrically conduct the source electrode 12 of each first semiconductor element 10A and the second conductive portion 32B. The first conductive member 5 forms a path for the main circuit current switched by the first semiconductor elements 10A. As shown in FIGS. 2 and 6, the first conductive member 5 includes a main portion 53, a plurality of fourth connection portions 51, and a plurality of fifth connection portions 52.

The main portion 53 is located between the first semiconductor elements 10A and the second conductive portion 32B in the first direction x, and has a strip shape extending in the second direction y in plan view. The main portion 53 is spaced apart from the first obverse surface 301A and the second obverse surface 301B to the z1 side in the thickness direction z. As shown in FIG. 14 in particular, the main portion 53 is located on the z2 side in the thickness direction z with respect to the main portion 63 of the second conductive member 6, described later.

In the present embodiment, the main portion 53 is parallel to the first obverse surface 301A and the second obverse surface 301B. The main portion 53 is formed with a plurality of first openings 514. The portions of the insulating layer 31 that are located between the first conductive portion 32A and the second conductive portion 32B are exposed from the first openings 514. The first openings 514 are formed to facilitate the flow of the resin material between the upper side (z1 side in the thickness direction z) and the lower side (z2 side in the thickness direction z) at or near the main portion 53 (the first conductive member 5) when the flowable resin material is injected to form the sealing resin 8.

As shown in FIG. 6 in particular, the fourth connection portions 51 and the fifth connection portions 52 are connected to the main portion 53. The fourth connection portions 51 are disposed to correspond to the first semiconductor elements 10A. Specifically, each of the fourth connection portions 51 is located on the x1 side in the first direction x with respect to the main portion 53. Each of the fifth connection portions 52 is located on the x2 side in the first direction x with respect to the main portion 53. As shown in FIG. 12, each of the fourth connection portions 51 and the source electrode 12 of a relevant one of the first semiconductor elements 10A are bonded via a conductive bonding material 59. Each of the fifth connection portions 52 and the second conductive portion 32B are bonded via a conductive bonding material 59. The constituent material of the conductive bonding material 59 is not particularly limited, and may be solder, metal paste or sintered metal, for example. In the present embodiment, each of the fourth connection portions 51 has two parts separated in the second direction y. These two parts are bonded to the source electrode 12 of the first semiconductor element 10A to flank the gate finger (not shown) of the source electrode 12 in the second direction y.

The second conductive member 6 is electrically connected to the source electrodes 12 of the second semiconductor elements 10B and the second terminal 42 to electrically conduct these. As shown in FIGS. 1, 4, and 18, the second terminal 42 and the second conductive member 6 form conduction paths Cp. The conduction paths Cp are located outside the first control terminals 46 in the second direction y. In the present embodiment, the second terminal 42 and the second conductive member 6 form two conduction paths Cp. One of the conduction paths Cp is located on the y1 side in the second direction y with respect to the first control terminals 46, while the other conduction path Cp is located on the y2 side in the second direction y with respect to the first control terminals 46. That is, the two conduction paths Cp are located on both outer sides in the second direction y of the first control terminals 46. In the illustrated example, the conduction paths Cp are shown by dashed lines for ease of understanding. The actual conduction direction of the conduction paths Cp is determined by the shapes of the second terminal 42 and the second conductive member 6 or other factors.

In the present embodiment, as shown in FIGS. 4, 13, and 14, the second conductive member 6 has a plurality of sixth connection portions 61, seventh connection portions 62, a main portion 63, a plurality of intermediate portions 64, two intermediate portions 65, and two intermediate portions 66.

The sixth connection portions 61 are individually bonded to the second semiconductor elements 10B. Each sixth connection portion 61 and the source electrode 12 of the relevant second semiconductor element 10B are bonded via a conductive bonding material 69. The constituent material of the conductive bonding material 69 is not particularly limited, and may be solder, metal paste or sintered metal, for example. In the present embodiment, each sixth connection portion 61 has two flat portions 611 and two first inclined portions 612.

The two flat portions 611 are arranged in the second direction y. The two flat portions 611 are spaced apart from each other in the second direction y. The shape of the flat portions 611 is not limited, and is rectangular in the illustrated example. The two flat portions are bonded to the source electrode 12 of the second semiconductor element 10B to flank the gate finger (not shown) of the source electrode 12 in the second direction y.

The two first inclined portions 612 are connected to the x1 side in the first direction x of the two flat portions 611. The first inclined portions 612 are inclined so as to shift toward the z1 side in the thickness direction z as proceeding away from the flat portions 611 in the first direction x.

The two seventh connection portions 62 are electrically connected to the second connection portion 422 of the second terminal 42. In the illustrated example, the seventh connection portions 62 are conductively bonded to the second connection portion 422. The methods of conductive bonding are not limited, and methods such as ultrasonic bonding, laser bonding, welding, or other methods using solder, metal paste, sintered silver or the like are used as appropriate. In the illustrated example, the seventh connection portions 62 are bonded to the second connection portion 422 via a conductive bonding material 69. The two seventh connection portions 62 are spaced apart from each other in the second direction y.

The main portion 63 is located between the sixth connection portions 61 and the seventh connection portions 62. The main portion 63 is a flat plate-like portion extending orthogonal to the thickness direction z.

The intermediate portions 64 are individually interposed between the sixth connection portions 61 and the main portion 63. In the illustrated example, the intermediate portions 64 are arranged radially from the main portion 63 toward the sixth connection portions 61.

The two intermediate portions 65 extend outward from the two seventh connection portions 62 in the second direction y. As shown in FIGS. 4, 10, and 15, the intermediate portions 65 overlap with the first connection portions 412 of the first terminals 41 in the thickness direction z. The intermediate portions 65 are positioned on the z1 side in the thickness direction z with respect to the first connection portions 412.

The two intermediate portions 66 are individually interposed between the main portion 63 and the two intermediate portion 65. The two intermediate portions 66 are located on both outer sides in the second direction y of the first control terminals 46. In the illustrated example, the intermediate portions 66 have extending portions 661. The extending portions 661 extend to the z2 side in the thickness direction z on the outer sides in the second direction y.

The sealing resin 8 covers the first semiconductor elements 10A, the second semiconductor elements 10B, the support substrate 3 (excluding the reverse surface 302), a part of each of the second terminal 42, the third terminal 43 and the two first terminals 41, a part of each of the control terminals 45, the control terminal support 48, the first conductive member 5, the second conductive member 6, and the wires 71, 72, and 74. The sealing resin 8 is made of, for example, black epoxy resin. The sealing resin 8 is formed by, for example, molding. The sealing resin 8 has dimensions of, for example, about 35 mm to 60 mm in the first direction x, about 35 mm to 50 mm in the second direction y, and about 4 mm to 15 mm in the thickness direction z. These dimensions are the size of the largest portion along each direction. The sealing resin 8 has a resin obverse surface 81, a resin reverse surface 82, and a plurality of resin side surfaces 831 to 834.

As shown in FIGS. 8, 10, and 16 in particular, the resin obverse surface 81 and the resin reverse surface 82 are spaced apart from each other in the thickness direction z. The resin obverse surface 81 faces the z1 side in the thickness direction z, and the resin reverse surface 82 faces the z2 side in the thickness direction z. The control terminals 45 (the first control terminals 46A to 46E and the second control terminals 47A to 47D) protrude from the resin obverse surface 81. As shown in FIG. 9, the resin reverse surface 82 has a frame shape surrounding the reverse surface 302 of the support substrate 3 (the lower surface of the reverse-surface metal layer 33) in plan view. The reverse surface 302 of the support substrate 3 is exposed at the resin reverse surface 82 and may be flush with the resin reverse surface 82.

Each of the resin side surfaces 831 to 834 is connected to the resin obverse surface 81 and the resin reverse surface 82 and disposed between these surfaces in the thickness direction z. As shown in FIG. 3 in particular, the resin side surface 831 and the resin side surface 832 are spaced apart from each other in the first direction x. The resin side surface 831 faces the x2 side in the first direction x, and the resin side surface 832 faces the x1 side in the first direction x. The third terminal 43 protrudes from the resin side surface 831, and the second terminal 42 and the first terminals 41 protrude from the resin side surface 832. As shown in FIG. 3 in particular, the resin side surface 833 and the resin side surface 834 are spaced apart from each other in the second direction y. The resin side surface 833 faces the y2 side in the second direction y, and the resin side surface 834 faces the y1 side in the second direction y.

As shown in FIG. 3, the resin side surface 832 is formed with a plurality of recesses 832a. Each recess 832a is a portion recessed in the first direction x in plan view. Each recess 832a is formed between the second terminal 42 and one of the first terminals 41 in plan view. The recesses 832a are provided to increase the creepage distance between the second terminal 42 and the first terminal 41 along the resin side surface 832.

As shown in FIGS. 3, 9 to 11, 14, and 15, the resin side surface 832 is formed with a plurality of recesses 832b. The recesses 832b are recessed from the resin side surface 832 to the x2 side in the first direction x. The first terminal portions 411 of the two first terminals 41 and the second terminal portion 421 of the second terminal 42 are exposed from the recesses 832b. The resin side surface 832 may not be formed with the recesses 832b, and the first terminal portions 411 and the second connection portion 422 may be configured to protrude from the resin side surface 832 to the x1 side in the first direction x.

As shown in FIGS. 11 and 18, the sealing resin 8 has a plurality of second protrusions 852. The second protrusions 852 protrude from the resin obverse surface 81 in the thickness direction z. The second protrusions 852 overlap with the control terminals 45 in plan view. The metal pins 452 of the control terminals 45 protrude from the second protrusions 852. Each second protrusion 852 has the shape of a truncated cone. Each second protrusion 852 covers the holder 451 and a part of the metal pin 452 of a control terminal 45.

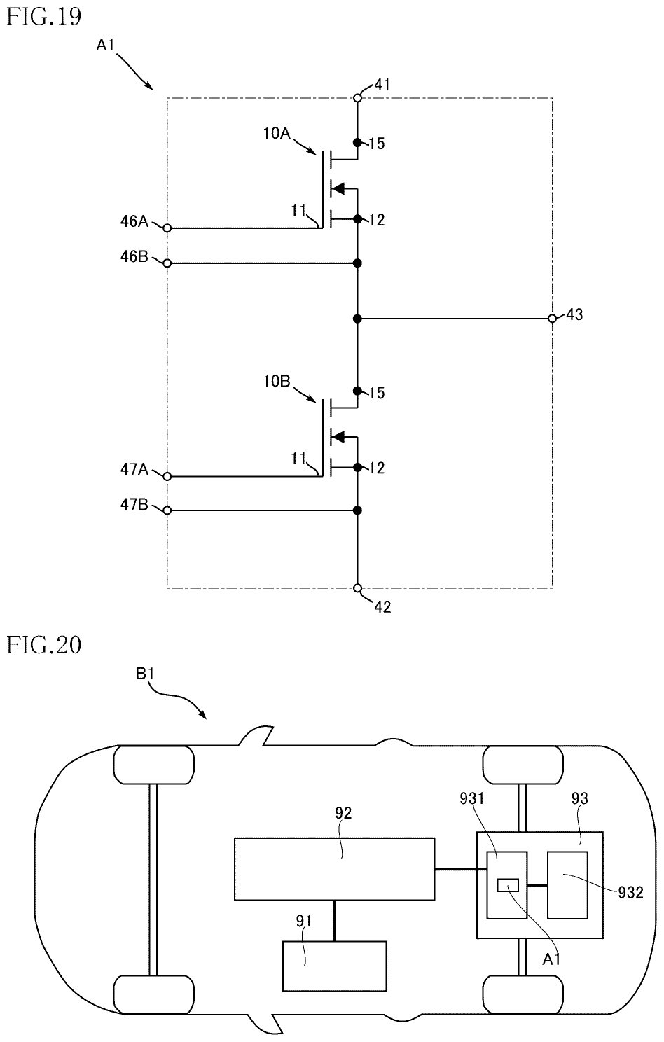

Next, a vehicle B1 in which the semiconductor device A1 is mounted will be described based on FIG. 20. The vehicle B2 may be, for example, an electric vehicle (EV).

As shown in FIG. 20, the vehicle B1 includes an on-board charger 91, a storage battery 92, and a drive system 93. The on-board charger 91 receives electric power wirelessly from a power supply facility (not shown) installed outdoors. Alternatively, power supply from the power supply facility to the on-board charger 91 may performed via a wired connection. The on-board charger 91 includes a step-up DC-DC converter. The voltage of the power supplied to the on-board charger 91 is increased by the converter and then supplied to the storage battery 92. The increased voltage is, for example, 600 V.

The drive system 93 drives the vehicle B1. The drive system 93 has an inverter 931 and a driving source 932. The semiconductor device A1 constitutes a part of the inverter 931. The power stored in the storage battery 92 is supplied to the inverter 931. The power supplied from the storage battery 92 to the inverter 931 is a DC power. Unlike the power system shown in FIG. 20, a step-up DC-DC converter may be additionally provided between the storage battery 92 and the inverter 931. The inverter 931 converts DC power into AC power. The inverter 931 including the semiconductor device A1 is electrically connected to the driving source 932.

The driving source 932 has an AC motor and a transmission. When the AC power converted by the inverter 931 is supplied to the driving source 932, the AC motor rotates, and the rotation is transmitted to the transmission. The transmission appropriately reduces the rotation speed transmitted from the AC motor and rotates the drive shaft of the vehicle B1. Thus, the vehicle B1 is driven. When driving the vehicle B1, it is necessary to freely control the rotation speed of the AC motor based on the information such as the amount of movement of the accelerator pedal. The semiconductor device A1 in the inverter 931 is necessary to output the AC power with a frequency corresponding to the required rotation speed of the AC motor.

Next, the effects of the semiconductor device A1 will be described.

As shown in FIGS. 1, 4, and 18, the conduction paths Cp formed by the second conductive member 6 and the second terminal 42 are located outside the first control terminals 46 in the second direction y. Thus, the second terminal 42 and the first control terminals 46 can be appropriately disposed while avoiding interference of the second conductive member 6 and the second terminal 42 with the first control terminals 46.

The second conductive member 6 and the second terminal 42 are configured as separate components. This prevents the individual components forming the conduction paths Cp from becoming excessively large.

In the semiconductor device A1, two conduction paths Cp are formed. The two conduction paths Cp are disposed on both outer sides in the second direction y of the first control terminals 46, bypassing the first control terminals 46 on the outer sides in the second direction y. This allows a larger current to flow to the second terminal 42 and the second conductive member 6 while avoiding interference of the second conductive member 6 and the second terminal 42 with the first control terminals 46.

As shown in FIGS. 4, 10, and 15, the intermediate portions 65 overlap with the first connection portions 412 as viewed in the thickness direction z, and are located on the z1 side in the thickness direction z with respect to the first connection portions 412. This allows more reliable insulation between the first terminal 41 and the second conductive member 6 while avoiding an increase in size as viewed in the thickness direction z of the semiconductor device A1.

The sixth connection portion 61 has two flat portions 611 and two first inclined portions 612. The two first inclined portions 612 are connected to the x1 side in the first direction x of the two flat portions 611. This suppresses concentration of the current flowing through the source electrode 12 at a single point.

The two flat portions 611 are spaced apart from each other in the second direction y. This enables reliable current flow through both the two flat portions 611 and the two first inclined portion 612, which is favorable for suppressing concentration of the current.

Since the two flat portions 611 are spaced apart from each other, the gate finger (not shown) of the source electrode 12 can be disposed between them.

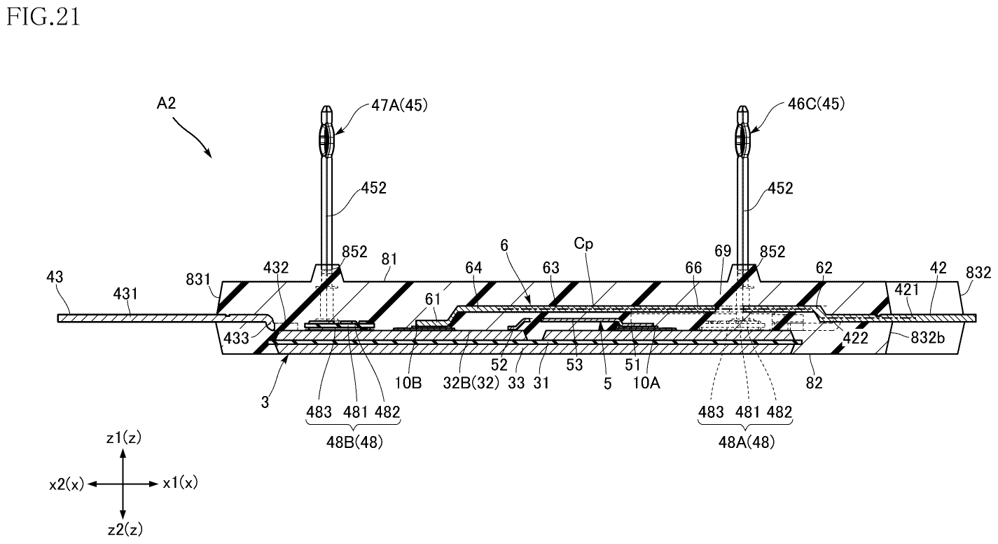

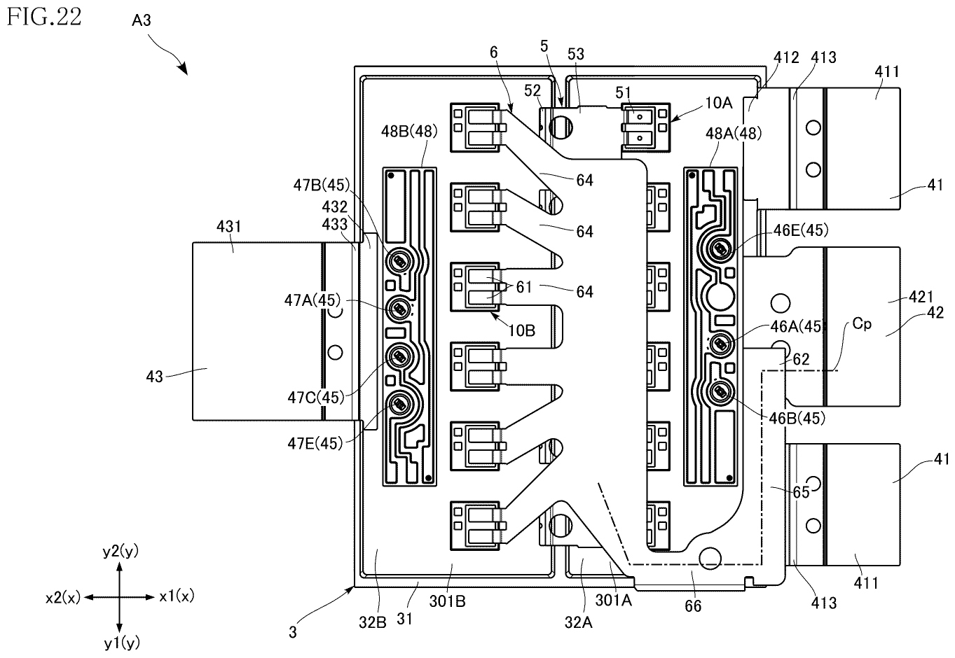

FIGS. 21 and 22 show other embodiments of the present disclosure. In these figures, the elements that are identical or similar to those of the above embodiment are denoted by the same reference signs as those used for the above embodiment. Various parts of embodiments may be selectively used in any appropriate combination as long as it is technically compatible.

FIG. 21 shows a semiconductor device according to a second embodiment of the present disclosure. The semiconductor device A2 of the present embodiment differs from the above embodiment in the configuration of the second conductive member 6 and the second terminal 42.

In the present embodiment, the second conductive member 6 and the second terminal 42 are configured as an integral unit. That is, the second conductive member 6 and the second terminal 42 are continuous without being bonded by a bonding part or the like.

In the present embodiment again, the second terminal 42 and the first control terminals 46 can be appropriately disposed. As understood from the present embodiment, the specific configuration of the second conductive member 6 and the second terminal 42, which form the conduction paths Cp, is not limited in any way. The electrical connection of the second conductive member 6 and the second terminal 42 is not limited to a configuration where the second conductive member 6 and the second terminal 42 are conductively bonded as in semiconductor device A1, but includes a configuration where the second conductive member 6 and the second terminal 42 are formed as an integral unit as in the present embodiment.

FIG. 22 shows a semiconductor device according to a third embodiment of the present disclosure. The semiconductor device A3 of the present embodiment differs from the above embodiments in the number of conduction paths Cp.

In the present embodiment, the second terminal 42 and the second conductive member 6 form a single conduction path Cp. The conduction path Cp of the present embodiment is located on the y1 side in the second direction y with respect to the first control terminals 46. The second conductive member 6 has one seventh connection portion 62, one intermediate portion 65, and one intermediate portion 66.

In the present embodiment again, the second terminal 42 and the first control terminals 46 can be appropriately disposed. As understood from the present embodiment, the number of conduction paths Cp is not limited in any way.

The semiconductor device and the vehicle according to the present disclosure are not limited to the embodiments described above. Various modifications in design may be made freely in the specific structure of each part of the semiconductor device and the vehicle according to the present disclosure. The present disclosure includes embodiments described in the following clauses.

### Clause 1

A semiconductor device comprising:
a first conductive portion;
a second conductive portion;
at least one first semiconductor element including a first electrode that is a positive electrode of a current path to be switched, a second electrode that is a negative electrode of the current path, and a third electrode that switches a conduction state between the first electrode and the second electrode;
at least one second semiconductor element including a first electrode that is a positive electrode of a current path to be switched, a second electrode that is a negative electrode of the current path, and a third electrode that switches a conduction state between the first electrode and the second electrode;
two first terminals;
a second terminal;
a third terminal;
a first conductive member;
a second conductive member;
a plurality of first control terminals;
a plurality of second control terminals; and
a sealing resin, wherein the first conductive portion includes a first obverse surface facing a first side in a thickness direction,
the second conductive portion includes a second obverse surface facing the first side in the thickness direction,
in a first direction orthogonal to the thickness direction, the first conductive portion is disposed on a first side, and the second conductive portion is disposed on a second side,
the first electrode of the first semiconductor element is conductively bonded to the first obverse surface,
the first electrode of the second semiconductor element is conductively bonded to the second obverse surface,
the plurality of first control terminals are located on the first side in the first direction with respect to the first semiconductor element, spaced apart from each other in a second direction orthogonal to the first direction and the thickness direction, and protrude toward the first side in the thickness direction relative to the first conductive portion,
the two first terminals are spaced apart from each other in the second direction, each connected to the first obverse surface, and protrude toward the first side in the first direction relative to the plurality of first control terminals,
the second terminal is located between the two first terminals in the second direction and protrudes toward the first side in the first direction relative to the plurality of first control terminals,
the third terminal is connected to the second obverse surface,
the first conductive member is conductively bonded to the second electrode of the first semiconductor element and the second obverse surface,
the second conductive member is conductively bonded to the second electrode of the second semiconductor element and the second terminal, and
the second terminal and the second conductive member form a conduction path located outside the plurality of first control terminals in the second direction.

### Clause 2

The semiconductor device according to clause 1, wherein the first terminal includes a first terminal portion exposed from the sealing resin and a first connection portion conductively bonded to the first obverse surface.

### Clause 3

The semiconductor device according to clause 2, wherein the second terminal includes a second terminal portion exposed from the sealing resin.

### Clause 4

The semiconductor device according to clause 3, wherein the third terminal includes a third terminal portion exposed from the sealing resin and a third connection portion conductively bonded to the second obverse surface.

### Clause 5

The semiconductor device according to clause 3 or 4, wherein the first conductive member includes a fourth connection portion conductively bonded to the second electrode of the first semiconductor element, and a fifth connection portion conductively bonded to the second obverse surface.

### Clause 6

The semiconductor device according to clause 5, comprising a plurality of first semiconductor elements spaced apart from each other in the second direction,
wherein the first conductive member includes a plurality of fourth connection portions individually conductively bonded to the second electrodes of the plurality of first semiconductor elements.

### Clause 7

The semiconductor device according to clause 6, wherein the first conductive member further includes a main portion interposed between the plurality of fourth connection portions and the fifth connection portion.

### Clause 8

The semiconductor device according to any one of clauses 3 to 7, further comprising a first support portion interposed between the plurality of first control terminals and the first conductive portion.

### Clause 9

The semiconductor device according to any one of clauses 3 to 8, wherein the second terminal and the second conductive member are separate members and conductively bonded to each other.

### Clause 10

The semiconductor device according to clause 9, wherein the second terminal includes a second connection portion extending from the second terminal portion toward the second side in the first direction, and the second connection portion and the second conductive member are conductively bonded.

### Clause 11

The semiconductor device according to clause 10, wherein the second conductive member includes a sixth connection portion conductively bonded to the second electrode of the second semiconductor element.

### Clause 12

The semiconductor device according to clause 11, comprising a plurality of second semiconductor elements spaced apart from each other in the second direction, wherein the second conductive member includes a plurality of sixth connection portions individually conductively bonded to the second electrodes of the plurality of second semiconductor elements.

### Clause 13

The semiconductor device according to clause 12, wherein the second conductive member further includes a seventh connection portion conductively bonded to the second connection portion, and a main portion interposed between the sixth connection portion and the seventh connection portion.

### Clause 14

The semiconductor device according to clause 13, wherein the second terminal and the second conductive member form two conduction paths located on both outer sides in the second direction of the plurality of first control terminals.

### Clause 15

The semiconductor device according to clause 14, wherein the second conductive member includes two seventh connection portions, and a plurality of intermediate portions that individually relay the main portion and the two seventh connection portions.

### Clause 16

The semiconductor device according to any one of clauses 3 to 8, wherein the second terminal and the second conductive member are an integral unit.

### Clause 17

A vehicle comprising:
a driving source; and
the semiconductor device as set forth in any one of clauses 1 to 16,
wherein the semiconductor device electrically conducts to the driving source.

### REFERENCE NUMERALS

A1, A2: Semiconductor device B1: Vehicle 3: Support substrate 5: First conductive member 6: Second conductive member 8: Sealing resin 10A: First semiconductor element 10B: Second semiconductor element 11: Gate electrode 12: Source electrode 13: Source sense electrode 15: Drain electrode 19A: First conductive bonding material 19B: Second conductive bonding material 31: Insulating layer 32: First metal layer 32A: First conductive portion 32B: Second conductive portion 33: Reverse-surface metal layer 41: First terminal 42: Second terminal 43: Third terminal 46, 46A, 46B, 46C, 46D, 46E: First control terminal 47A, 47B, 47C, 47D, 47E: Second control terminal 48: Control terminal support 48A: First support portion 48B: Second support portion 49: Bonding material 51: Fourth connection portion 52: Fifth connection portion 53: Main portion 59: Conductive bonding material 61: Sixth connection portion 62: Seventh connection portion 63: Main portion 64: Step portion 66: Third path portion 69: Conductive bonding material 71, 72, 74: Wire 81: Resin obverse surface 82: Resin reverse surface 91: On-board charger 92: Storage battery 93: Drive system 101: Element obverse surface 102: Element reverse surface 301A: First obverse surface 301B: Second obverse surface 302: Reverse surface 411: First terminal portion 412: First connection portion 413: First step portion 421: Second terminal portion 422: Second connection portion 431: Third terminal portion 432: Third connection portion 451: Holder 452: Metal pin 459: Conductive bonding material 481: Insulating layer 482: First metal layer 482A: First portion 482B: Second portion 482C: Third portion 482E: Fifth portion 483: Second metal layer 514: First opening 602: First step portion 603: Second step portion 611: Flat portion 612: First inclined portion 831: Resin side surface 832: Resin side surface 832a, 832b: Recess 833, 834: Resin side surface 852: Second protrusion 931: Inverter 932: Driving source Cp: Conduction path Tb: Thickness x: First direction y: Second direction z: Thickness direction

1. A semiconductor device comprising:
a first conductive portion;
a second conductive portion;
at least one first semiconductor element including a first electrode that is a positive electrode of a current path to be switched, a second electrode that is a negative electrode of the current path, and a third electrode that switches a conduction state between the first electrode and the second electrode;
at least one second semiconductor element including a first electrode that is a positive electrode of a current path to be switched, a second electrode that is a negative electrode of the current path, and a third electrode that switches a conduction state between the first electrode and the second electrode;
two first terminals;
a second terminal;
a third terminal;
a first conductive member;
a second conductive member;
a plurality of first control terminals;
a plurality of second control terminals; and
a sealing resin, wherein
the first conductive portion includes a first obverse surface facing a first side in a thickness direction,
the second conductive portion includes a second obverse surface facing the first side in the thickness direction,
in a first direction orthogonal to the thickness direction, the first conductive portion is disposed on a first side, and the second conductive portion is disposed on a second side,
the first electrode of the first semiconductor element is conductively bonded to the first obverse surface,
the first electrode of the second semiconductor element is conductively bonded to the second obverse surface,
the plurality of first control terminals are located on the first side in the first direction with respect to the first semiconductor element, spaced apart from each other in a second direction orthogonal to the first direction and the thickness direction, and protrude toward the first side in the thickness direction relative to the first conductive portion,
the two first terminals are spaced apart from each other in the second direction, each connected to the first obverse surface, and protrude toward the first side in the first direction relative to the plurality of first control terminals,
the second terminal is located between the two first terminals in the second direction and protrudes toward the first side in the first direction relative to the plurality of first control terminals,
the third terminal is connected to the second obverse surface,
the first conductive member is conductively bonded to the second electrode of the first semiconductor element and the second obverse surface,
the second conductive member is conductively bonded to the second electrode of the second semiconductor element and the second terminal, and
the second terminal and the second conductive member form a conduction path located outside the plurality of first control terminals in the second direction.

2. The semiconductor device according to claim 1, wherein the first terminal includes a first terminal portion exposed from the sealing resin and a first connection portion conductively bonded to the first obverse surface.

3. The semiconductor device according to claim 2, wherein the second terminal includes a second terminal portion exposed from the sealing resin.

4. The semiconductor device according to claim 3, wherein the third terminal includes a third terminal portion exposed from the sealing resin and a third connection portion conductively bonded to the second obverse surface.

5. The semiconductor device according to claim 3, wherein the first conductive member includes a fourth connection portion conductively bonded to the second electrode of the first semiconductor element, and a fifth connection portion conductively bonded to the second obverse surface.

6. The semiconductor device according to claim 5, comprising a plurality of first semiconductor elements spaced apart from each other in the second direction,
wherein the first conductive member includes a plurality of fourth connection portions individually conductively bonded to the second electrodes of the plurality of first semiconductor elements.

7. The semiconductor device according to claim 6, wherein the first conductive member further includes a main portion interposed between the plurality of fourth connection portions and the fifth connection portion.

8. The semiconductor device according to claim 3, further comprising a first support portion interposed between the plurality of first control terminals and the first conductive portion.

9. The semiconductor device according to claim 3, wherein the second terminal and the second conductive member are separate members and conductively bonded to each other.

10. The semiconductor device according to claim 9, wherein the second terminal includes a second connection portion extending from the second terminal portion toward the second side in the first direction, and
the second connection portion and the second conductive member are conductively bonded.

11. The semiconductor device according to claim 10, wherein the second conductive member includes a sixth connection portion conductively bonded to the second electrode of the second semiconductor element.

12. The semiconductor device according to claim 11, comprising a plurality of second semiconductor elements spaced apart from each other in the second direction,
wherein the second conductive member includes a plurality of sixth connection portions individually conductively bonded to the second electrodes of the plurality of second semiconductor elements.

13. The semiconductor device according to claim 12, wherein the second conductive member further includes a seventh connection portion conductively bonded to the second connection portion, and a main portion interposed between the sixth connection portion and the seventh connection portion.

14. The semiconductor device according to claim 13, wherein the second terminal and the second conductive member form two conduction paths located on both outer sides in the second direction of the plurality of first control terminals.

15. The semiconductor device according to claim 14, wherein the second conductive member includes two seventh connection portions, and a plurality of intermediate portions that individually relay the main portion and the two seventh connection portions.

16. The semiconductor device according to claim 3, wherein the second terminal and the second conductive member are an integral unit.

17. A vehicle comprising:
a driving source; and
the semiconductor device as set forth in claim 1,
wherein the semiconductor device electrically conducts to the driving source.
